(19) United States
(12) Patent Application Publication
(10) Pub. No.: US 2009/0305465 A1
(43) Pub. Date: Dec. 10, 2009

(54) MICROBUMP SEAL

(75) Inventor: John U. Knickerbocker, Monroe, NY (US)

Correspondence Address: SCULLY, SCOTT, MURPHY & PRESSER, P.C., 400 GARDEN CITY PLAZA, SUITE 300, GARDEN CITY, NY, 11530, US

(73) Assignee: INTERNATIONAL BUSINESS MACHINES CORPORATION, Armonk, NY (US)

(21) Appl. No.: 12/543,131

(22) Filed: Aug. 18, 2009

Related U.S. Application Data
(62) Division of application No. 11/775,432, filed on Jul. 10, 2007.

(51) Int. Cl. H01L 21/50; H01L 21/54; H01L 21/70

(52) U.S. Cl. 438/109; 257/E21.501; 257/E21.532; 257/E21.499

(57) ABSTRACT

A sealable microelectronic device providing mechanical stress endurance which includes a semiconductor substrate. A substantially continuous sealing element is positioned adjacent an outer periphery and between a microelectronic component and the semiconductor substrate, or another microelectronic component. The sealing element seals the microelectronic component to the substrate or another microelectronic component, and provides structural support to the microelectronic device.

### CROSS-REFERENCE TO RELATED APPLICATIONS

This application is a divisional of U.S. patent application Ser. No. 11/775,432, filed Jul. 10, 2007.

### BACKGROUND

The present invention relates to a semiconductor IC (integrated circuit) chip packaging, generally, and more specifically, relates to a sealing element for sealing and structurally supporting microelectronic devices.

Integrated circuits (ICs) form the basis for many electronic systems. Integrated circuits require the use of an increasing number of linked transistors and other circuit elements. An integrated circuit or chip includes a vast number of transistors and other circuit elements that are formed on a single semiconductor wafer and are interconnected to implement a desired function.

Many modern electronic systems use a variety of different integrated circuits, where each integrated circuit (IC or chip) performs one or more specific functions. For example, computer systems include at least one microprocessor and a number of memory chips. Typically, each of these integrated circuits (ICs) are formed on a separate chip, packaged independently, and interconnected on, for example, a printed circuit board (PCB), or logic board.

In micoelectronics, a wafer is a thin slice of semiconducting material, such as a silicon crystal, upon which microcircuits are constructed, for example, by doping, etching, or deposition. Wafers are used in the fabrication of semiconductor devices or, for example, semiconductor structures, such as integrated circuits or chips or dies. A single wafer may have a plurality of chips formed on the wafer. The wafer may be used having a plurality of chips formed therein, or the wafer may be cut to provide individual dies or chips. The wafers and chips or dies can form a stack by positioning the wafers and chips, two wafers, or two chips on top of one another. Copper bonding (Cu bonding) processes can be used to stack dies/chips at a chip-to-chip, chip-to-wafer, or wafer-to-wafer level.

As integrated circuit (IC) technology progresses, a need for a “system on a chip” in which the functionality of all of the IC devices of the system are packaged together without a conventional printed circuit board (PCB). Ideally, a computing system should be fabricated with all the necessary IC devices on a single chip. In practice, however, it is very difficult to implement a truly high-performance “system on a chip” because of vastly different fabrication processes and different manufacturing yields for the logic and memory circuits.

As a compromise, various “system modules” have been introduced that electrically connect and package integrated circuit (IC) devices which are fabricated on the same or on different semiconductor wafers. Initially, system modules have been created by simply stacking two chips, e.g., a logic and memory chip, on top of one another in an arrangement commonly referred to as a chip-on-chip device. Subsequently, multi-chip module (MCM) technology has been utilized to stack a number of chips on a common substrate to reduce the overall size and weight of the package which directly translates into reduced system size.

Existing multi-chip module (MCM) technology provides performance enhancements over single chip or chip-on-chip (COC) packaging approaches. For example, when several semiconductor chips are mounted and interconnected on a common substrate using high density interconnects, higher silicon packaging density and shorter chip-to-chip interconnections can be achieved. In addition, low dielectric constant materials and higher wiring density can also be obtained, which leads to increased system speed and reliability, reduced weight, volume, power consumption, and heat to be dissipated for the same level of performance. However, MCM packaging approaches still suffer from additional problems, such as, bulky packaging, wire length, and wire bonding that gives rise to stray inductances which interfere with the operation of the system module.

A microelectronic device may use solder microbumps for small size interconnections. Also, a device may use copper interconnections, as well as other interconnection used in chip stacking technology, and may include thinned Si wafers. Typically, optimization of Cu bonding utilizes one pattern density with specific bond pad dimensions and via dimensions. Vias and electrically connected pads refer to vias/pads with a plated hole that connects conductive tracks from one layer of a chip to another layer(s). Current solutions are not compatible with standard CMOS processes in which a variety of pattern densities and pad/via sizes may be used. Additionally, due to mechanical stability issues most of the bonding fails occur at the edge of the bonded pattern which often, in addition to degraded bonding yield, leads to corrosion issues. Additionally, for 3D applications, a method or device is needed to provide additional protection from mechanical damage (such as crack propagation, chipping, dicing, etc.) caused by mechanical stresses during the semiconductor fabrication process.

In the current state of the art, electrically active bonded pads and vias are placed in a central location of the feature pattern on the chip or wafer to provide acceptable reliability for these contacts. One major challenge of three dimensional (3-D) wafer-to-wafer vertical stack integration technology is the metal bonding between wafers and between die in a single chip. Also, another challenge is protecting the wafer from possible corrosion and contamination caused or generated by process steps after the wafers are bonded, from reaching active IC devices on the bonded wafers.

Therefore, a need exits during semiconductor device fabrication and in packaging, for example, using fine pitch interconnections, to provide the ability to seal and rework, or the ability to underfill to enhance the life of a microbump. Additionally, a need exists to reduce corrosion, enhance thermal transfer, support high gravitational forces (G forces), and to improve overall structural integrity of a microelectronic device.

### BRIEF SUMMARY

In an aspect of the invention, a microelectronic device includes a plurality of microelectronic components each having an outer periphery. At least one substantially continuous sealing element is positioned between a pair of microelectronic components. The at least one substantially continuous sealing element is positioned substantially adjacent the outer periphery of the microelectronic components for sealing the microelectronic components together, and for providing structural support to the microelectronic device.

In a related aspect, at least one of the microelectronic components, is a substrate, and the substrate and a microelectronic component and the at least one substantially continuous sealing element define a substantially sealed cavity and a sealable microelectronic package.

In a related aspect, wherein the sealing element is in spaced adjacency to the outer periphery of the plurality of microelectronic components.

In a related aspect, the device further includes a plurality of substantially continuous sealing elements positioned substantially adjacent the outer periphery of the plurality of microelectronic components and in spaced relation to each other.

In a related aspect, the plurality of microelectronic components each have an outer periphery. A plurality of substantially continuous sealing elements are between the semiconductor substrate and between each of the plurality of microelectronic components. Each of the substantially continuous sealing elements is positioned substantially adjacent the outer periphery of each of the plurality of microelectronic components for sealing each of the plurality of microelectronic components to each other, and for sealing at least one of the microelectronic components to the substrate providing structural support to the microelectronic device.

In a related aspect, the plurality of microelectronic components and the semiconductor substrate and the plurality of sealing elements define a substantially sealed cavity. The plurality of microelectronic components are electrically connected to the substrate to form an electrical circuit on the plurality of microelectronic components substantially isolated from each other by the plurality of sealing elements.

In a related aspect, at least one of the plurality of microelectronic components is a chip electrically connected to the semiconductor device at a plurality of locations.

In a related aspect, the at least one sealing element is a first sealing element and the device further includes a heat sink positioned over the chip; and a second sealing element positioned substantially adjacent the outer periphery of the chip and in spaced relation to the first sealing element.

In a related aspect, the chip is a first chip and the at least one substantially continuous sealing element is a first substantially continuous sealing element, and the device further includes a second chip having an outer periphery and a second substantially continuous sealing element positioned substantially adjacent the outer periphery of the second chip. The second chip is formed substantially in the first chip and the second substantially continuous sealing element provides sealing between the first and second chips.

In a related aspect, the first chip is a silicon chip package.

In a related aspect, at least one of the plurality of microelectronic components is a first silicon wafer including a first plurality of chips and the at least one substantially continuous sealing element is a first substantially continuous sealing element. The device further includes a second silicon wafer having an outer periphery and including a second plurality of chips and a second substantially continuous sealing element positioned substantially adjacent the outer periphery of the second wafer. The second wafer is formed substantially on the first wafer, and the second substantially continuous sealing element providing sealing between the first and second wafers.

In a related aspect, at least one of the plurality of microelectronic components, and the at least one substantially continuous sealing element define a substantially sealed cavity. The device further includes the microelectronic component defining an aperture extending therethrough and the aperture providing access to the substantially sealed cavity. A gas substantially fills the cavity, and the aperture is filled with a sealing material.

In a related aspect, at least one of the microelectronic component is a wafer including a plurality of chips and the semiconductor substrate, the wafer, and the at least one substantially continuous sealing element define a substantially sealed cavity. The device further includes the wafer defining an opening extending therethrough and the opening providing access to the substantially sealed cavity. Also, a laser diode, for emitting a laser beam or a photo detector for receiving an optical signal, is positioned on the substrate and accessible through the opening.

In a related aspect, the sealing element is compressed and/or heated for sealing the plurality of microelectronic components together.

In a related aspect, the plurality of microelectronic components includes a plurality of chips positioned on at least one wafer. The sealing element is positioned substantially adjacent an outer periphery of the plurality of chips and an outer periphery of the at least one wafer. Further, the sealing element is compressed and heated for sealing the chips and the wafer to another microelectronic component or the substrate.

In another aspect of the invention, a sealable microelectronic package provides mechanical stress endurance comprising a semiconductor substrate, and a plurality of microelectronic components each having an outer periphery and mounted on one another. A plurality of substantially continuous sealing elements are formed between the microelectronic components and the semiconductor substrate or another microelectronic component. The plurality of substantially continuous sealing elements are positioned substantially adjacent the outer periphery of the microelectronic components for sealing the microelectronic components to each other or the substrate and for providing structural support to the microelectronic device.

In another aspect of the invention, a method for manufacturing a microelectronic device comprises providing a plurality of microelectronic components; mounting at least one microelectronic component having an outer periphery on another microelectronic component or a substrate; and positioning at least one substantially continuous sealing element substantially adjacent the outer periphery of the at least one microelectronic component and between the microelectronic component and another microelectronic component for sealing the microelectronic components together, and for providing structural support to the microelectronic device.

In a related aspect, the method further includes compressing overlapping microelectronic components to bond a plurality of sealing elements together, and/or heating the sealing elements to seal overlapping microelectronic components together or seal a microelectronic component to the substrate.

In a related aspect, the method further includes defining a cavity between at least one microelectronic component and the substrate or another microelectronic component; forming an aperture in at least one microelectronic component communicating with the cavity; filling the cavity with a gas through the aperture; and sealing the aperture to form a sealed microelectronic package.

In a related aspect, the method further includes a wafer including multiple chips; positioning at least one sealing element adjacent a periphery of the wafer; overlapping the wafer and another microelectronic component to define a cavity therebetween; defining an opening in the wafer; and positioning a laser diode for emitting a laser beam or a photodetector device for receiving an optical signal on the substrate through the opening.

### BRIEF DESCRIPTION OF THE SEVERAL VIEWS OF THE DRAWINGS

These and other objects, features and advantages of the present invention will become apparent from the following detailed description of illustrative embodiments thereof, which is to be read in connection with the accompanying drawings, in which:

FIG. 1 is a cross sectional side elevational view of a microelectronic device according to an embodiment of the invention depicting a plurality of stacked chips and sealing elements;

FIG. 2 is a cross sectional side elevational view of a microelectronic device according to another embodiment of the invention depicting a heat sink, and a plurality of chips and sealing elements;

FIG. 3 is a cross sectional side elevational view of a microelectronic device according to another embodiment of the invention having a single chip over a silicon package with solder balls or microbumps therebetween;

FIG. 4 is a cross sectional plan view of the device shown in FIG. 3 depicting the sealing element and the solder balls;

FIG. 5 is a cross sectional side elevational view of a microelectronic device according to another embodiment of the invention depicting a chip, vias, sealing elements, solder balls, and multiple seals between the chip and the Si package;

FIG. 6 is cross sectional plan view of the device shown in FIG. 5 depicting the sealing elements and solder balls;

FIG. 7 is a cross sectional plan view of another embodiment of a microelectronic device according to the present invention depicting a wafer having a sealing element, a plurality of chips each having sealing elements and solder balls, and a cavity in the wafer;

FIG. 8 is a detailed view of one of the chips shown in FIG. 7 further including sealing elements around each solder ball or microbump;

FIG. 9 is a cross sectional side elevational view of the device shown in FIG. 7 depicting the cavity;

FIG. 10 is a cross sectional plan view of the device shown in FIG. 9 depicting the sealing elements, the solder balls, and the cavity; and

FIG. 11 is a cross sectional side elevational view of another embodiment of a microelectronic device according to the present invention depicting a chip within a chip.

### DETAILED DESCRIPTION

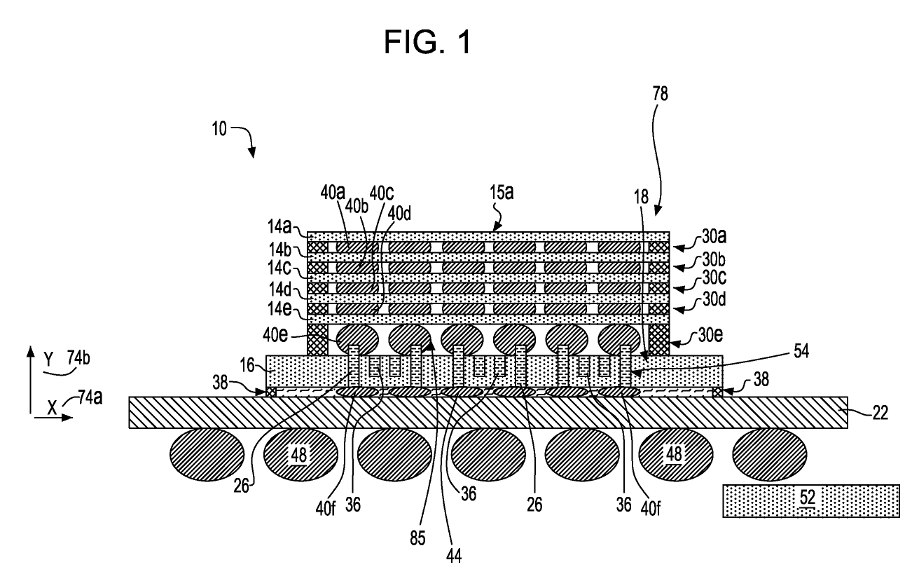

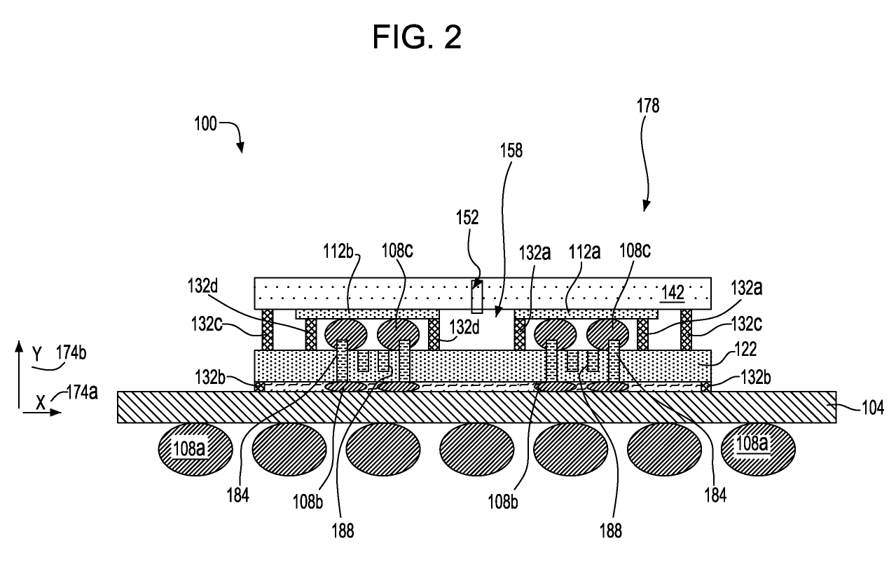

In an illustrative embodiment of the invention, a seal or sealing structure is shown in FIG. 1 and comprises sealing elements 30a-30e for joining microelectronic components, for example, a chip (Integrated circuits (IC)) 14e to a Silicon (Si) package 16 and ultimately, a substrate 22, to form a sealed microelectronic device 10, which includes, for example, microelectronic packages or structures. In another embodiment, referring to FIG. 2, a chip or a microprocessor 112a is joined to a Silicon (Si) package 122 (i.e, a silicon (Si) carrier) using a sealing element 132a. Similarly, a chip or a microprocessor 112b is joined to the Si package 122 using a sealing element 132d. Further referring to FIG. 2, a sealing element 132b is used for joining the Si package 122 to the substrate 104 to create a seal between the Si package 122 and the substrate 104. Additionally, referring to FIG. 2, a sealing element 132c is used for joining a heat sink 142 (e.g., a cooling cap or thermal heat spreader or a microchannel cooler) to the back of chips 112a, 112b. Moreover, a sealing element 132c is used for joining the heat sink 142 to the Silicon package 122. The sealing elements 30a-30e and 132a-132d shown in FIGS. 1 and 2, respectively, may be composed of, alone or in combination, for example, solder, a polymer, or a metallic material (e.g., Cu, Ni or alternate metal).

More specifically, referring to FIGS. 1 and 2, chips 14a-14e are positioned in a stack, and Si packages 16, 122 are joined to the substrates 22, 104, respectively, which may further be joined or connected with a circuit or logic board 52, shown in FIG. 1. The sealing elements 30a-30e between the stacked chips 14a-14e, respectively, may, for example, be composed of solder and thus create a solder seal between the chips 14a-14e. Alternatively, the sealing elements may be composed of copper to provide a copper seal between the chips. During manufacturing, a copper sealing element forming a copper sealing joint may be provided during chip to chip copper interconnection bonding. Similarly, copper sealing elements may be used during Si package bonding to a substrate, or during other copper to copper interconnection processes used in microelectronic applications.

Further referring to FIG. 1, the sealed microelectronic device or package 10 provides mechanical enhancement, thermal enhancement, chip stacking capabilities, for example, singular chips on Si packages or Si packages stacked on each other. Further, the device or package 10 also may include 3D structures having a cavity 85 which can be filed with a liquid, atmosphere, or, singularly or in combination, a gas to provide corrosion protection. The sealed microelectronic device 10 can also be used for small size interconnections such as solder microbumps, copper interconnections, and other interconnection used in chip stacking technology, and may include thinned Si wafers. The chips 14a-14e shown in FIG. 1 are stacked one over another, and collectively over the Si package 16 and the substrate 22, and over the circuit board 52. The chips 14a-14e are electrically connected by conductive vias 26 to solder balls 40f, which are electrically connected (not shown) through the substrate 22 to the solder balls 48, and further to the circuit board 52. The chips 14a-14e are sealed to each other adjacent to their edges or periphery by sealing elements 30a-30d. Further, decoupling capacitors (decaps) or integrated decaps may be formed in trench structures 36 formed in the substrate 16, and thus integrated into the silicon substrate and thereby the package. Decaps in the trenches 36 provide a stored electrical charge which assists in chip power control so as to minimize noise or avoid significant voltage droop.

Referring to FIG. 1, the substrate 22 supports the stack of thin chips 14a-14e positioned over a series of solder balls 40e. The substrate 16 is sealed adjacent the periphery of the thin chip 14e by sealing element 30e which seals the chip stack comprising thin chips 14a-14e to the substrate 16. Thus, the seals 30a-30e form a column-like line of seals along the opposing ends of the thin chips 14a-14e, as shown in FIG. 1. The conductive vias 26 electrically connect the solder balls 40e with corresponding solder balls 40f beneath the substrate 16. The substrate 16 is positioned over the circuit board 22 with solder balls 40f between the substrate 16 and the circuit board 22. A sealing element 38 is positioned adjacent the periphery of the Si package 16 and provides sealing between the substrate 22 and the Si package 16. Solder balls 48 are positioned beneath the circuit board 22 to provide electrical connection with other components (not shown).

A sealing element according to the present invention may also be used to surround or ring the surface of a thinned Si chip to provide a “crack stop” for thinned Si dies and for stacked Si dies. The sealing element according to the present invention also enhances stress capabilities during handling, or mechanical manipulation of a chip or package. Examples of surface metallurgies including etched patterns to improve crack stops in handling or processing for thinned dies, and wafers, and thinned packages, may include Ti, W, Cu, Ni, Au, Cr, CrCu, TaN, TiN or other metallurgies which can be embedded, through vias, surface pads, rings or segments, and, or in combination with, microbump seals between features. Further, crack stop patterns on a chip or wafer may include, for example, polymers, oxides and or combinations thereof, and may be applied, for example, on Si wafers or chips having a thickness less than 200 μm thickness.

Referring to FIG. 1, the microelectronic device 10 also provides a hermitic seal for the Si package 16 which seals chips 14a-14e to the Si package 16. The microelectronic device 10 thereby, hermetically seals or encapsulate microbumps or solder balls and other electrical connections while providing support and reducing corrosion. Further, the sealing elements may be composed of a composite of material to strengthen the device 10.

More specifically, referring to FIG. 2, a sealed microelectronic device or package 100 includes sealing elements 132a-132c. Similar to the device 10, shown in FIG. 1, chips 112a, 112b are electrically connected by vias 184 to solder balls 108b, and trenches 188 are formed in the substrate 122 to provide decoupling capacitors (decaps) or integrated decaps. A hole 152 through the heat sink 142 allows access to the sealed package 100. After fabrication, the microelectronic package 100 is sealed to define a cavity 158 therein, the cavity can be filled with an inert gas (for example, Ar, N2 or He to reduce corrosion or enhance thermal transport), or a liquid or oil (for example, silicon oil or an alternate) which encourages corrosion protection and thermal conductivity. The hole 152 allows access to fill the cavity, and then is sealed, for example, with polymer seal, solder, a screw, or a rubber O-ring, or by curing a filler in the hole 152 to form a solid, thereby sealing the hole 152 to provide the sealed package 100. The resulting sealed package 100 provides enhanced structural properties provided by, for example, a copper to copper seal, as well as, corrosion protection by sealing the package 100.

It is understood that the microelectronic package 10, shown in FIG. 1 may also be sealed similarly to the microelectronic package 100, shown in FIG. 2. The sealed packages 10, 100 advantageously discourages corrosion by preventing contamination of semiconductor features by materials, gases, or liquids which encourage corrosion. Further, forming the sealed packages may include compressing and heating the sealing elements 30a-30e, 132a-132c, shown for example in FIGS. 1 and 2, to bond the sealing elements to their respective components, and or alternatively the substrate. The sealed package 10, 100, for example, stops unwanted entry of, for example, materials, substances, or debris into the package.

Further the sealed packages 10, 100 are thermally enhancement by providing a thermal conduction path. The sealed packages 10, 100 provide thermal enhancement by the sealing element, for example, being composed of solder which thermal conductivity provides for heat conduction (solder thermal conductivity is about 40 watts/meter/degree K). However, Si has a better thermal conductivity (about 140 w/M/K) than solder. For example, Copper has about 350 w/M/K, which is better than SiO₂ at about 2 to 4 w/M/K, which are all better than many polymers which are about 0.2 W/M/K. Filling the cavity 158 provides better thermal conductivity than the cavity being filled with air because air has a thermal conductivity which is much lower than, for example, a polymer. Moreover, the thermal conductivity can be increased by incorporating one or more of the following features into the seal, such as increasing the area or width of a solder sealing element, decreasing the thickness of the seal, or using a material or combination of materials or filled materials with higher thermal conductivity for the seal or stacked device including the seal.

In an alternative embodiment, the sealing element may comprise a silver filled polymer which, in a similar manner as discussed above regarding solder, provides thermal conduction. Alternatively, He gas can be used to fill the cavity and has substantially better thermal conductivity than air, Nitrogen or Argon. Another alternative includes using oil to fill any gaps inside the sealing element to enhances the thermal conductivity of the sealing element and reduce corrosion. The oil or liquid needs to be appropriately compatible with other metals or conductors used.

The sealed packages 10, 100 are also advantageous, for example, by providing, alone or in combination, enhanced adhesion between the components of the package 10, 100 which support high gravitational forces (G forces), torsion forces and other stresses the package may be subjected to during processing or in application. The sealing elements 30a-30d and 132a-132c, of the embodiments shown in FIGS. 1 and 2, respectively, provide support of the microelectronic components, for example, the chip stack 14a-14e and substrate shown in FIG. 1, and the chips 112a-112b and the heat sink 142 shown in FIG. 2. The microelectronic components have a weight producing axial forces 78, 178 as shown in FIGS. 1 and 2, respectively. The axial forces 78, 178 are perpendicular to the “X” axis' 74a, 174a and along the “Y” axis' 74b, 174b, respectively. More particularly, the axial forces 78, 178 are from, for example, the weight of the chips 14a-14e shown in FIG. 1, or axial force (or pressure) from the weight of other chips (or wafers) stacked above chips or wafers and ultimately on the substrate 22. More specifically, when additional chips are stacked one over another or other microelectronic components are positioned in overlapping relation to other components as shown in FIGS. 2, 3, 5, 9 and 11, additional axial forces from the weight of additional chips bear down (along the “Y” axis 74b) on the outer top surface 18 of the Si package 16 from the chip stack 14a-14e, the solder balls 40e and the column-like sealing elements 30a-30d. The sealing elements 30a-30e further facilitate stabilizing the bonded wafer 250 against torsional forces (or stresses), which may occur in the processing or fabricating of the wafer or from disproportionate weight distribution from stacking other chips (or wafers) over one another such that twisting or bending occurs along the surface areas of the chips 14a-14e. If torsion stresses are applied, for example, to the package 10 (shown in FIG. 1) and thereby the chips 14a-14e, the torsion causes twisting of the package 10, and chips 14a-14e that may result in shearing stress which are perpendicular to the chips' surface areas (the surface area 15a of chip 14a is illustratively shown in FIG. 1 for the remaining chips 14b-14e). The sealing elements receive axial and torsion forces as do the other components in the package, and thereby increase the distribution of the axial and torsion forces throughout the package. The distribution of forces lessens the forces in one particular area, thereby reducing the stress in that area and decreasing the likelihood of a stress related fracture or break in the chip or wafer device.

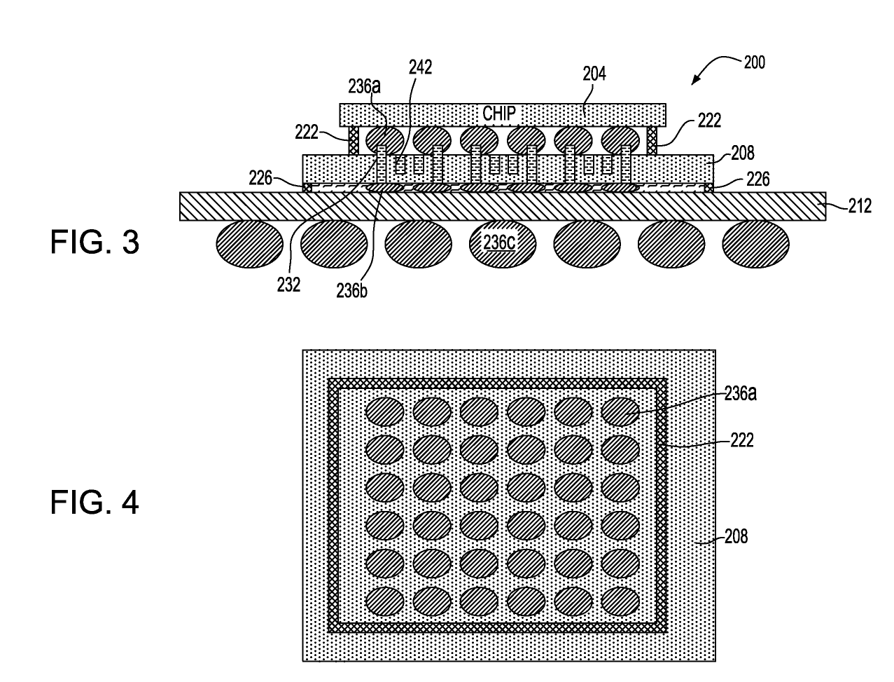

Referring to FIGS. 3 and 4, another embodiment of a sealed microelectronic device or package 200 includes sealing elements 222, 226 sealing a chip 204 to a Si package 208, and the Si package 208 to a substrate 212, respectively. Similar to the devices 10 and 100, shown in FIGS. 1 and 2, chip 204 is electrically connected to solder balls 236a and 236b by vias 232. The solder balls 236b are electrically connected (not shown) to the substrate 212 and other solder balls 236c which can be electrically connected to a circuit board (not shown). Similarly to the devices 10 and 100 shown in FIGS. 1 and 2, trenches 242 are formed in the substrate 212 to provide decoupling capacitors (decaps) or integrated decaps.

Referring to FIG. 4, the sealing element 222 is shown around the perimeter of the Si package 208. The solder balls 236a are sealed by the sealing element 222 from external electrical interference as well as unwanted debris. The sealing element 222 shown in FIG. 4 exemplifies the sealing arrangement of electrical components, in this case the Si package 208 to the chip 204 with solder balls 236a between them. Thus, a cross section through the solder balls 236b between the substrate and the Si package would depict a similar seal around the solder balls 236b. Further, as similarly discussed regarding the devices 10, 100 shown in FIGS. 1 and 2, the resulting sealed package 200 provides enhanced structural properties provided by, for example, a copper to copper join, as well as corrosion protection by sealing the package 200.

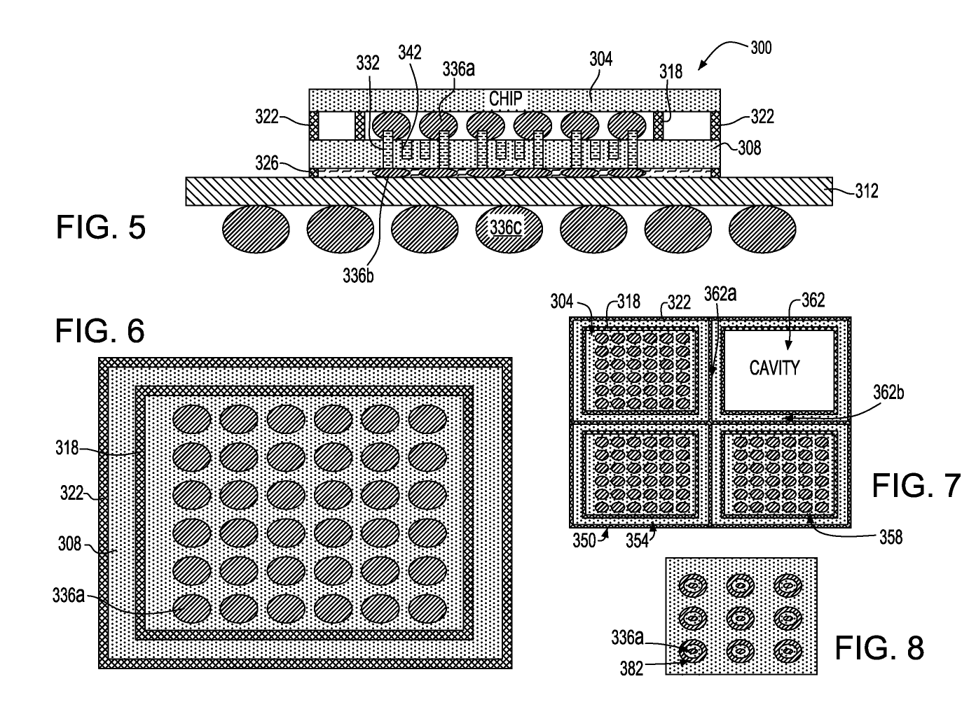

Referring to FIGS. 5 and 6, another embodiment of a sealed microelectronic device or package 300 includes two sealing elements 318, 322 sealing a chip 304 to a Si package 308, and sealing element 326 sealing the Si package 308 to a substrate 312. Similar to the devices 10, 100, 200 shown in FIGS. 1-4, chip 304 is electrically connected to solder balls 336a and 336b by vias 332. The solder balls 336b are electrically connected (not shown) to the substrate 312 and other solder balls 336c beneath the substrate 312, can be electrically connected to a circuit board (not shown). Similarly to the devices 10, 100, and 200 shown in FIGS. 1-4, trenches 342 are formed in the substrate 312 to provide decoupling capacitors (decaps) or integrated decaps.

Referring to FIG. 6, the sealing elements 318, 322 provide a double seal around the perimeter of the Si package 308, as shown in a cross sectional view passing through the solder balls 336a between the chip 304 and the Si package 308. The solder balls 336a are sealed by both the sealing elements 318, 322 from external electrical interference as well as unwanted debris. As similarly discussed regarding the devices 10, 100 and 200 shown in FIGS. 1-4, the resulting sealed package 300 provides enhanced structural properties provided by, for example, a copper to copper join, as well as corrosion protection by sealing the package 300.

Referring to FIGS. 7 and 8, in another embodiment of the invention, related to device 300, shown in FIGS. 5 and 6 includes the Si package which mates with the chip 304 as part of a wafer 350 having additional chips 354, 358. Each chip 304, 354, 358 is isolated by associated sealing elements, shown illustratively by sealing element 322 and 318 of chip 304. The sealing elements surround the perimeter of each chip and the perimeter of the wafer by the contiguous nature of each segment of the sealing elements. Using chip 304 for illustrative purposes, the solder balls 336a are surrounded by both the sealing elements 318 and 322 which form an inner and an outer seal, respectively. Sealing element 322 forms an outer seal and a contiguous perimeter seal for the wafer 350. Also, sealing elements 362a and 362b vertically and horizontally, respectively, segment the wafer 350 between the chips 304, 354, 358.

Further, the wafer 350 includes an opening 362. The opening 362 allows access to a sealed cavity 366 defined by the chip 304 and the Si package 308, and sealed by the sealing elements 318, 322. The cavity 366 may contain, for example, a laser diode (not shown) for emitting a laser beam or a photo detector (not shown) for receiving an optical signal. The laser diode or photo detector may be positioned on the substrate 312 and accessible through the opening 362.

Referring to FIG. 8, a further embodiment according to the invention, of device 300, shown in FIGS. 5 and 6 includes the portion of the Si package 308 mating with the chip 304, having solder balls 336a or microbumps sealed by sealing elements 382. Thus, each solder ball 336a or microbump is sealed individually or in combination with the sealing elements as shown in FIGS. 5-7. The sealing elements 382 can also provide electrical isolation of the solder balls 336a from other surrounding electronic components.

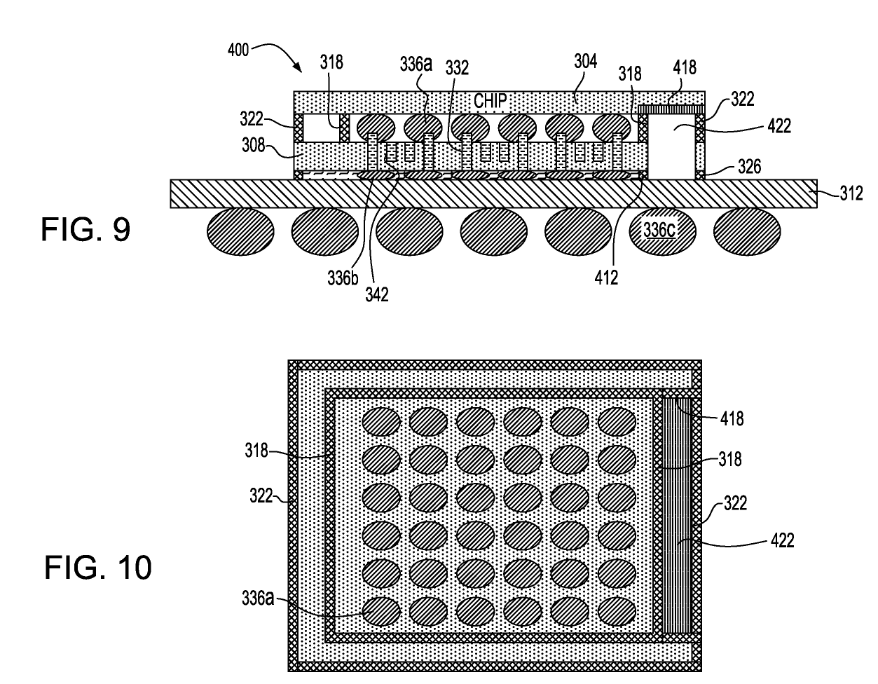

Referring to FIGS. 9 and 10, another embodiment of a sealed microelectronic device or package 400 is similar to the package 300 shown in FIGS. 5 and 6, and like reference numerals are used for the same elements. The package 400 includes two sealing elements 318, 322 sealing the chip 304 to the Si package 308. Additionally, a cavity is defined 422 between the chip 304 and the Si package substrate 312. Also, sealing element 418 and 412 provide sealing at the top and side of the cavity 422 between the Si package 308 and the substrate 312, as shown in FIGS. 9 and 10. The cavity 422 can house, for example, a laser diode (not shown) for emitting a laser beam, for example, a VCSEL (Vertical-Cavity Surface-Emitting Laser), or a photo detector (not shown) for receiving an optical signal both of which can be positioned on the substrate 312.

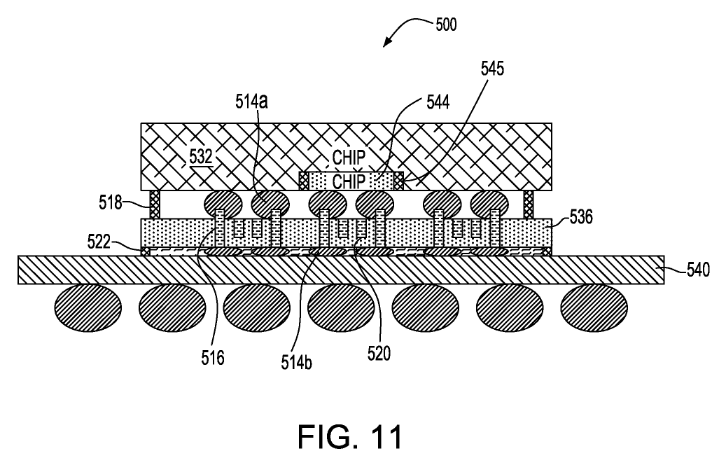

Referring to FIG. 11, another embodiment of a sealed microelectronic device or package 500 includes a sealing element 518 between a first or outer Si package 532 and a second Si package 536. Another sealing element 522 is between the Si package 536 and a substrate 540. An inner chip 544 is encompassed on three sides by the outer package 532 and includes sealing element 545 around a perimeter of the chip 544. The sealing element 545, thereby provides a seal between the outer package 532 and the inner chip 544. In a similar manner to the devices 10, 100, 200, 300, 400 generally shown in FIGS. 1-10, both the outer package 532 and the inner chip 544 are electrically connected to solder balls 514a and 514b by vias 516. However, in the package 500, shown in FIG. 11, some of the solder balls 514a and their associated vias 516 are dedicated to the outer package 532 and the rest, are dedicated to the inner chip 544. Additionally, the solder balls 514a are electrically connected (not shown) to the substrate 540, and solder balls 514b beneath the Si package 536 can be electrically connected to a circuit board (not shown). In a similar manner to the devices 10, 100, 200, 300, and 400 generally shown in FIGS. 1-10, trenches 520 are formed in the substrate Si package 536 to provide decoupling capacitors (decaps) or integrated decaps.

Thus, in the above described embodiments, for microprocessor fabrication and packages, using, for example, fine pitch interconnections, the ability to seal and rework, or the ability to underfill are enhanced using the present invention in improving the life of microbumps or solder connections. Additionally, the present invention reduces corrosion, enhances thermal transfer, supports high G forces, and improves overall structural integrity.

While the present invention has been particularly shown and described with respect to preferred embodiments thereof, it will be understood by those skilled in the art that changes in forms and details may be made without departing from the spirit and scope of the present application. It is therefore intended that the present invention not be limited to the exact forms and details described and illustrated herein, but falls within the scope of the appended claims.

What is claimed is:

1. A method for manufacturing a microelectronic device, comprising:
providing a plurality of microelectronic components;
mounting at least one microelectronic component having an outer periphery on another microelectronic component or a substrate; and
positioning at least one substantially continuous sealing element substantially adjacent the outer periphery of the at least one microelectronic component and between the microelectronic component and another microelectronic component for sealing the microelectronic components together, and for providing structural support to the microelectronic device.

2. The method of claim 1, further including:
compressing overlapping microelectronic components to bond a plurality of sealing elements together; and/or
heating the sealing elements to seal overlapping microelectronic components together or seal a microelectronic component to the substrate.

3. The method of claim 1, further including:
defining a cavity between at least one microelectronic component and the substrate or another microelectronic component;
forming an aperture in at least one microelectronic component communicating with the cavity;
filling the cavity with a gas through the aperture; and
sealing the aperture to form a sealed microelectronic package.

4. The method of claim 1, further including:
a wafer including multiple chips;
positioning at least one sealing element adjacent a periphery of the wafer;
overlapping the wafer and another microelectronic component to define a cavity therebetween;
defining an opening in the wafer; and
positioning a laser diode for emitting a laser beam or a photodetector device for receiving an optical signal on the substrate through the opening.
